(19) United States
(12) Patent Application Publication
(10) Pub. No.: US 2012/0326204 A1
(43) Pub. Date: Dec. 27, 2012

(54) ORGANIC LIGHT EMITTING DIODE LIGHTING APPARATUS

(75) Inventors: Yong-Han Lee, Yongin-city (KR); Ok-Keun Song, Yongin-city (KR); Doo-Hwan Kim, Yongin-city (KR); Sung-Jin Choi, Yongin-city (KR)

(73) Assignee: Samsung Mobile Display Co., Ltd., Yongin-city (KR)

(21) Appl. No.: 13/452,539

(22) Filed: Apr. 20, 2012

(30) Foreign Application Priority Data
Jun. 22, 2011 (KR) 10-2011-0060883

(51) Int. Cl. H01L 33/00

(52) U.S. Cl. 257/100; 257/E33.059

(57) ABSTRACT

An organic light emitting diode lighting apparatus is disclosed. In one embodiment, the apparatus includes: a substrate main body, an organic light emitting element formed on the substrate main body and a sealing cap bonded with the substrate main body and covering and sealing the organic light emitting element. The sealing cap may further include a surface facing the organic light emitting element and the surface is divided into a plurality of thickness parts having different thicknesses.

### RELATED APPLICATIONS

This application claims priority to and the benefit of Korean Patent Application No. 10-2011-0060883 filed in the Korean Intellectual Property Office on Jun. 22, 2011, the entire contents of which are incorporated herein by reference.

### BACKGROUND

1. Field

The described technology generally relates to a lighting apparatus, more particularly, to an organic light emitting diode (OLED) lighting apparatus using an organic light emitting element.

2. Description of the Related Technology

An OLED lighting apparatus uses light emitted from an OLED. OLEDs emit light when excitons generated by combining electrons and holes in an organic emission layer fall from an exited state to a ground state.

Since OLED lighting apparatuses mainly generate light instead of displaying an image, they can have a relatively simple structure compared to a display device that displays an image based on a separate light source.

### SUMMARY

One inventive aspect is an organic light emitting diode lighting apparatus simultaneously having a display function by using luminance deviation of light emitted from an organic light emitting element with a simple structure.

Another aspect is an organic light emitting diode lighting apparatus which includes: a substrate main body; an organic light emitting element formed on the substrate main body; and a sealing cap bonded with the substrate main body and covering and sealing the organic light emitting element. The sealing cap includes a surface facing the organic light emitting element and the surface is divided into a plurality of thickness parts having different thicknesses.

The plurality of thickness parts may include a first thickness part and a second thickness part having a thinner thickness than the first thickness part.

The second thickness part may be separated relatively farther from the organic light emitting element than the first thickness part.

The organic light emitting element corresponding to the second thickness part may emit light having relatively higher luminance than the organic light emitting element corresponding to the first thickness part.

The difference between the thickness of the first thickness part and the thickness of the second thickness part may be equal to or larger than about 100 μm.

The first thickness part may have a thickness in the range of about 300 μm to about 600 μm, and the second thickness part may have a thickness in the range of about 200 μm to about 500 μm.

The entire thickness of the sealing cap may be in the range of about 400 μm to about 900 μm.

The second thickness part of the sealing cap may be formed such that a portion of the surface facing the organic light emitting element is recessed.

In the organic light emitting diode lighting apparatus, the sealing cap may be one of a metal cap made of a metal material and a glass cap made of a glass material.

The second thickness part may be formed with a figure including at least one of numbers, characters, and symbols.

The luminance of the light emitted from the organic light emitting element may be equal to or larger than about 1000 nit.

According to an exemplary embodiment, the organic light emitting diode lighting apparatus has a simple structure and simultaneously displays an image by using luminance deviation of light emitted from the organic light emitting element.

### BRIEF DESCRIPTION OF THE DRAWINGS

FIG. 1 is a cross-sectional view of an organic light emitting diode lighting apparatus according to an embodiment.

FIG. 2 is a bottom perspective view of a sealing cap of the organic light emitting diode lighting apparatus shown in FIG. 1.

FIG. 3 and FIG. 4 are photos of experimental examples according to embodiments.

### DETAILED DESCRIPTION

Some OLED lighting apparatuses may need a display function for displaying a simple image according to a functional or aesthetic necessity as well as the light emission. However, such OLED lighting apparatuses may result in an overly complex structure.

Embodiments will be described more fully hereinafter with reference to the accompanying drawings. The described embodiments may be modified in various different ways.

Like reference numerals designate like elements throughout the specification.

Further, the size and thickness of each of elements that are displayed in the drawings are arbitrarily described for better understanding and ease of description, and the present invention is not limited by the described size and thickness.

In the drawings, the thickness of layers, films, panels, regions, etc., may be exaggerated for clarity. In the drawings, for better understanding and ease of description, thicknesses of some layers and areas are excessively displayed. It will be understood that when an element such as a layer, film, region, or substrate is referred to as being “on” another element, it can be directly on the other element or intervening elements may also be present.

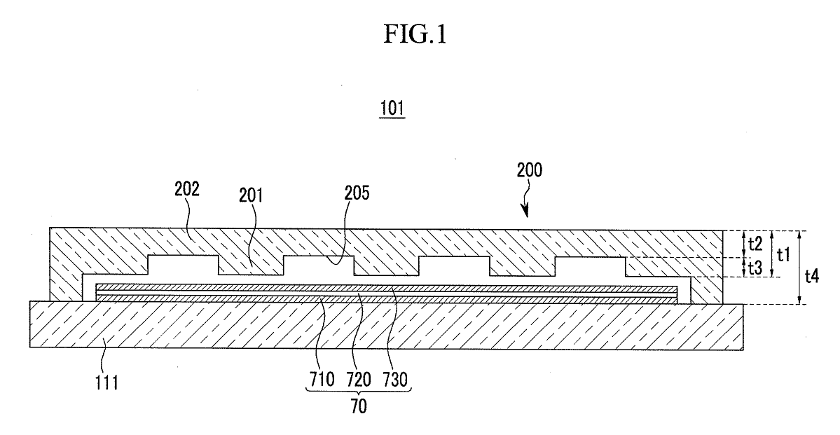

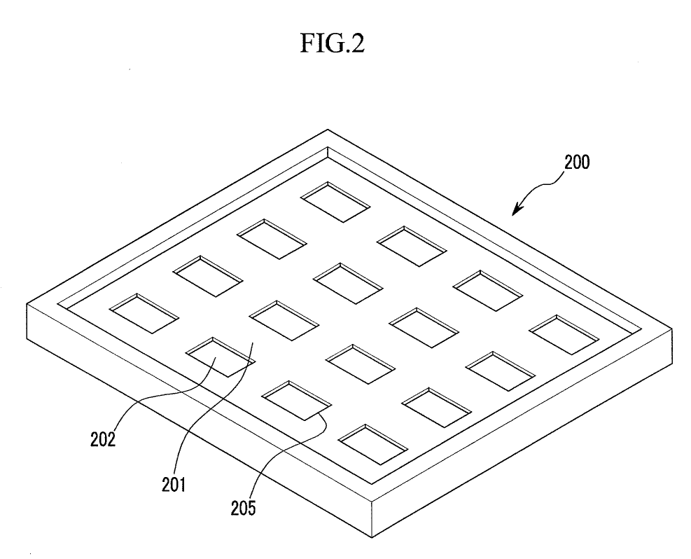

Now, referring to FIG. 1 and FIG. 2, an organic light emitting diode lighting apparatus 101 according to an embodiment will be described.

As shown in FIG. 1, an OLED lighting apparatus 101 includes a substrate main body 111 (or a substrate), an organic light emitting element 70, and a sealing cap 200. Although not shown, the OLED lighting apparatus 101 may further include a sealant bonding and sealing the substrate main body 111 and the sealing cap 200.

In one embodiment, the substrate main body 111 is formed to be a transparent insulating substrate made of glass, crystal, or ceramic, or a transparent flexible substrate made of plastic.

The organic light emitting element 70 includes a first electrode 710, an organic emission layer 720, and a second electrode 730.

In one embodiment, the first electrode 710 is an anode that is a hole injection electrode, and the second electrode 730 is a cathode that is an electron injection electrode. However, the first electrode 710 may be the electron injection electrode and the second electrode 730 may be the hole injection electrode.

In one embodiment, the first electrode 710 is made of a transparent conductive layer or a transflective layer, and the second electrode 730 is formed of a reflective layer.

The transparent conductive layer may be made of a material of indium tin oxide (ITO), indium zinc oxide (IZO), zinc oxide (ZnO), or indium oxide (In₂O₃). The transparent conductive layer has a relatively high work function. Accordingly, the first electrode 710 formed with the transparent conductive layer may smoothly execute the hole injection. Also, when the first electrode 710 is formed with the transparent conductive layer, the OLED lighting apparatus 101 may further include an assistance electrode made of a metal having relatively low resistivity to compensate the relatively high resistivity of the first electrode 710.

The reflective layer and the transflective layer may be made of at least one of metal of magnesium (Mg), silver (Ag), gold (Au), calcium (Ca), lithium (Li), chromium (Cr), and aluminum (Al), or alloys thereof. Here, the reflective layer and the transflective layer are determined by thickness. In general, the transflective layer has a thickness of less than about 200 nm. For the transflective layer, as the thickness is thinner, the transmittance of the light is increased, and as the thickness is thicker, the transmittance of the light is decreased.

When the first electrode 710 is formed with the transflective electrode and the second electrode 730 is formed with the reflective layer, light usage efficiency may be improved by using a microcavity effect.

Also, the first electrode 710 may be formed with a multilayered structure including the transparent conductive layer and the transflective layer. In this case, the first electrode 710 may simultaneously have the microcavity effect while having the high work function.

In one embodiment, the organic emission layer 720 is formed as a multilayer including at least one of an emission layer, a hole injection layer (HIL), a hole transport layer (HTL), an electron transport layer (ETL), and an electron injection layer (EIL). The layers except for the emission layer among the above-described layers may be omitted if necessary. In the case that the organic emission layer 720 includes all of the layers, the hole injection layer (HIL) is disposed on the first electrode 710 being the hole injection electrode, and is sequentially overlaid with the hole transport layer (HTL), the emission layer, the electron transport layer (ETL), and the electron injection layer (EIL). Also, the organic emission layer 720 may include other layers when needed.

In one embodiment, the organic light emitting element 720 emits light having luminance of more than about 1000 nit (cd/m²) at a minimum.

In one embodiment, the OLED lighting apparatus has a bottom emission structure in which light generated from the organic emission layer 720 is emitted outside through the first electrode 710 and the substrate main body 111.

The sealing cap 200 is bonded with the substrate main body 111, thereby sealing and covering the organic light emitting element 70. As shown in FIG. 1 and FIG. 2, the sealing cap 200 is divided into a plurality of thickness parts 201 and 202 (or portions) of which the surface facing the organic light emitting element 70 has different thicknesses.

In one embodiment, the thickness parts include a first thickness part 201 (or a first portion) and a second thickness part 202 (or a second portion). In another embodiment, three or more than thickness parts having different thicknesses of the sealing cap 200 may be included.

In one embodiment, the second thickness part 202 has a thinner thickness than the first thickness part 201 by more than about 100 μm. That is, the thickness difference t3 between the first and second thickness parts 201 and 202 is more than about 100 μm. Also, the second thickness part 202 is separated relatively farther from the organic light emitting element 70 than the first thickness part 201. That is, a portion 205 of the sealing cap 200 corresponding to the organic light emitting element 70 is recessed, thereby forming the second thickness part 202.

The second thickness part 202 may be formed with a figure including at least one of numbers, characters, and symbols. Here, the symbols include a polygon, a circle, and various shapes.

In one embodiment, the second thickness part 202 has a thinner thickness than the first thickness part 201, thereby having a relatively small heat-radiating effect. In this embodiment, the organic light emitting element 70 corresponding to the second thickness part 202 has a higher temperature than the organic light emitting element 70 corresponding to the first thickness part 201. Also, the organic light emitting element 70 corresponding to the second thickness part 202 emits light having higher luminance than the organic light emitting element 70 corresponding to the first thickness part 201. This is because the voltage is decreased if the temperature is increased under the characteristic of the organic light emitting element 70. Accordingly, the OLED lighting apparatus 101 may display a simple image by using the luminance deviation of the organic light emitting element 70 due to the thickness difference between the first and second thickness parts 201 and 202 and the shape of the second thickness part 202.

Also, for example, the first thickness part 201 may have a thickness t1 in the range of about 300 μm to about 600 μm, and the second thickness part 202 may have a thickness in the range of about 200 μm to about 500 μm. The entire thickness t4 of the sealing cap 200 is in the range of about 400 μm to about 900 μm.

If the thickness of the first thickness part 201 is less than about 300 μm, the heat-radiating effect may be seriously decreased and sufficient intensity to protect the organic light emitting element 70 may not be provided. On the other hand, if the first thickness part 201 is thicker than about 600 μm, the entire thickness of the OLED lighting apparatus 200 may become too thick.

The thickness t2 of the second thickness part 202 is determined to be more than about 100 μm less than the first thickness part 201. Also, the entire thickness t4 of the sealing cap 200 is determined by considering the thickness t1 of the first thickness part 201 and the separation distance between the first thickness part 201 and the organic light emitting element 70.

By this constitution, the OLED lighting apparatus 101 may simultaneously have the display function by using the luminance difference of the light emitted from the organic light emitting element 70 while having the simple structure.

In one embodiment, the luminance deviation of the organic light emitting element 70 is generated by the thickness difference between the first and second thickness parts 201 and 202 of the sealing cap 200. Also, the second thickness part 202 may be formed with the figure including the numbers, the characters, and the symbols, and the simple image may be displayed by using the luminance deviation of the organic light emitting element 70. That is, the shape of the second thickness part 202 may become the image displayed by the organic light emitting diode lighting apparatus 101.

On the other hand, if the thickness difference between the first thickness part 201 and the second thickness part 202 of the sealing cap 200 is less than about 100 μm, the luminance deviation according to the heat-radiating effect may be slight. Accordingly, to effectively display the image through the organic light emitting diode lighting apparatus 101, the thickness difference between the first thickness part 201 and the second thickness part 202 may be at least about 100 μm.

Also, the sealing cap 200 may be one of a metal cap made of a metal material and a glass cap made of a glass material. The sealing cap 200 made of the metal cap has an excellent heat-radiating effect, however the heat-radiating effect may also be maximized in the case that the sealing cap 200 is made of the glass cap according to an embodiment.

Also, the OLED lighting apparatus 101 may display the image when emitting light at more than the predetermined luminance. If the luminance of light emitted from the organic light emitting element 70 is less than about 1000 nit under the characteristic of the organic light emitting element 70, the heating amount of the organic light emitting element 70 is small such that the influence of the heat-radiating difference between the first and second thickness parts 201 and 202 of the sealing cap 200 is small. That is, the entire temperature deviation of the organic light emitting element 70 may become weak. Accordingly, the luminance deviation between the organic light emitting element 70 corresponding to the second thickness part 202 and the organic light emitting element 70 corresponding to the first thickness part 201 is slight. Meanwhile, if the luminance of the light emitted from the organic light emitting element 70 is more than about 1000 nit, the organic light emitting element 70 emits relatively high heat. Accordingly, the entire temperature deviation of the organic light emitting element 70 is increased by the influence of the heat-radiating difference between the first thickness part 201 and the second thickness part 202 of the sealing cap 200. Therefore, the luminance deviation is generated between the organic light emitting element 70 of the second thickness part 202 and the organic light emitting element 70 corresponding to the first thickness part 201 is generated, and thereby the organic light emitting diode lighting apparatus 101 may display the image through this.

As described above, the organic light emitting diode lighting apparatus 101 may not only simply display the image, but may also display the image with the predetermined luminance.

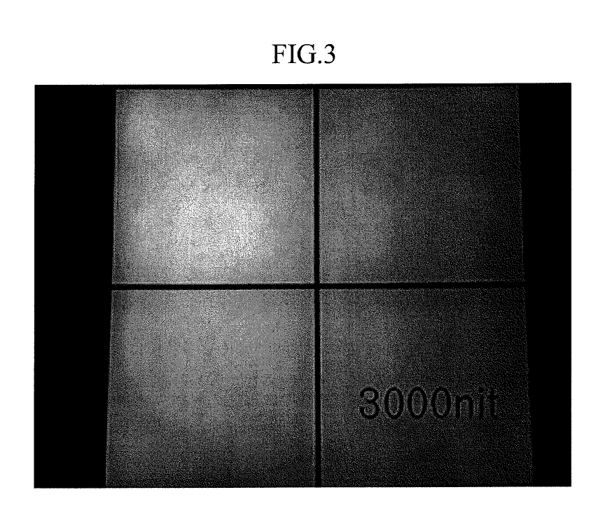

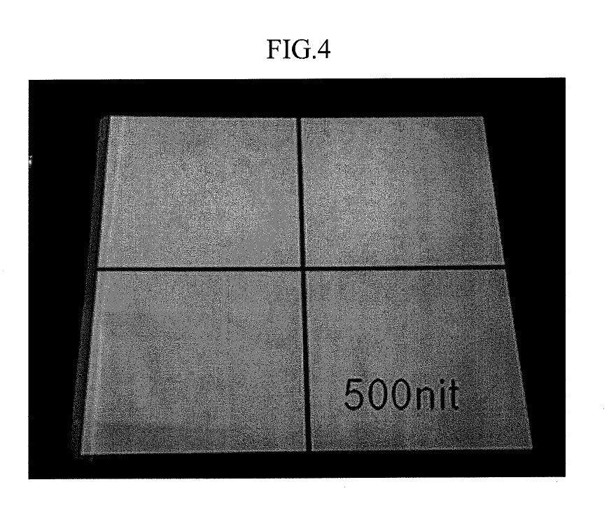

Next, referring to FIG. 3 and FIG. 4, experimental examples according to an embodiment will be described. The experimental examples use the sealing cap 200 according to an embodiment as shown in FIG. 2. Here, the sealing cap 200 is the metal cap. FIG. 3 shows an experimental example emitting light having luminance of 3000 nit on average, and FIG. 4 shows an experimental example emitting light having luminance of 500 nit on average.

The experimental example shown in FIG. 3 emits light having luminance of 3000 nit on average, it may be confirmed that the image of the shape like the second thickness part 202 (shown in FIG. 2) of the sealing cap 200 is displayed.

The experimental example shown in FIG. 4 emits light having luminance of 500 nit on average, it may be confirmed that the image is not displayed.

Through these experimental examples, the OLED lighting apparatus 101 having the simple structure may not only simply display the image by using the luminance difference of the light emitted from the organic light emitting element 70, but may also display the image with the predetermined luminance.

While the disclosed embodiments have been described with respect to the accompanying drawings, it is to be understood that the disclosed embodiments are not considered limiting, but, on the contrary, they are intended to cover various modifications and equivalent arrangements included within the spirit and scope of the appended claims.

What is claimed is:

1. An organic light emitting diode lighting apparatus comprising:
a substrate;
an organic light emitting element formed on the substrate; and
a sealing cap bonded to the substrate so as to cover and seal the organic light emitting element,
wherein the sealing cap includes a surface facing the organic light emitting element, and wherein the surface is divided into a plurality of portions having different thicknesses.

2. The organic light emitting diode lighting apparatus of claim 1, wherein the portions include a first portion and a second portion having a thickness that is thinner than the first portion.

3. The organic light emitting diode lighting apparatus of claim 2, wherein the second portion is separated relatively farther from the organic light emitting element than the first portion.

4. The organic light emitting diode lighting apparatus of claim 2, wherein the organic light emitting element corresponding to the second portion is configured to emit light having relatively higher luminance than the organic light emitting element corresponding to the first portion.

5. The organic light emitting diode lighting apparatus of claim 2, wherein the difference between the thicknesses of the first and second portions is substantially equal to or larger than about 100 μm.

6. The organic light emitting diode lighting apparatus of claim 5, wherein the first portion has a thickness in the range of about 300 μm to about 600 μm, and wherein the second portion has a thickness in the range of about 200 μm to about 500 μm.

7. The organic light emitting diode lighting apparatus of claim 6, wherein the entire thickness of the sealing cap is in the range of about 400 μm to about 900 μm.

8. The organic light emitting diode lighting apparatus of claim 1, wherein the second portion is recessed from the perspective of the organic light emitting element.

9. The organic light emitting diode lighting apparatus of claim 1, wherein the sealing cap is a metal cap formed of a metal material or a glass cap formed of a glass material.

10. The organic light emitting diode lighting apparatus of claim 9, wherein the second portion is formed with a figure including at least one of numbers, characters, and symbols.

11. The organic light emitting diode lighting apparatus of claim 10, wherein the luminance of the light emitted from the organic light emitting element is substantially equal to or larger than about 1000 nit.
